(19) United States
(12) Patent Application Publication
(10) Pub. No.: US 2022/0155758 A1
(43) Pub. Date: May 19, 2022

(54) SYSTEMS AND METHODS FOR INTEGRATED COMPONENT-BASED CONSTRUCTION

(71) Applicant: IP FACTORS, LLC, Los Angeles, CA (US)

(72) Inventor: Farhad Vafaee, Los Angeles, CA (US)

(21) Appl. No.: 17/527,678

(22) Filed: Nov. 16, 2021

Related U.S. Application Data
(60) Provisional application No. 63/114,323, filed on Nov. 16, 2020.
(60) Provisional application No. 63/114,341, filed on Nov. 16, 2020.
(60) Provisional application No. 63/114,349, filed on Nov. 16, 2020.
(60) Provisional application No. 63/114,390, filed on Nov. 16, 2020.
(60) Provisional application No. 63/114,401, filed on Nov. 16, 2020.
(60) Provisional application No. 63/114,408, filed on Nov. 16, 2020.
(60) Provisional application No. 63/114,417, filed on Nov. 16, 2020.
(60) Provisional application No. 63/114,426, filed on Nov. 16, 2020.
(60) Provisional application No. 63/114,452, filed on Nov. 16, 2020.
(60) Provisional application No. 63/114,460, filed on Nov. 16, 2020.
(60) Provisional application No. 63/114,468, filed on Nov. 16, 2020.
(60) Provisional application No. 63/114,472, filed on Nov. 16, 2020.
(60) Provisional application No. 63/114,476, filed on Nov. 16, 2020.
(60) Provisional application No. 63/114,485, filed on Nov. 16, 2020.
(60) Provisional application No. 63/114,489, filed on Nov. 16, 2020.
(60) Provisional application No. 63/114,492, filed on Nov. 16, 2020.
(60) Provisional application No. 63/115,497, filed on Nov. 18, 2020.
(60) Provisional application No. 63/114,755, filed on Nov. 17, 2020.

(51) Int. Cl. G05B 19/4155

(52) U.S. Cl. CPC G05B 19/4155; G05B 2219/32019

(57) ABSTRACT

A method of integrated component-based construction includes receiving construction project input data comprising characteristics of a construction project and preparing a centralized construction model based on the construction project input data and on a component library. The component library includes a plurality of construction components having a plurality of predetermined characteristics. The methods also includes determining a construction plan based on the centralized construction model comprising a plurality of factors and sending fabrication instruction data and factor data based on the centralized construction model. The fabrication instruction data includes fabrication instructions for the construction components in the centralized construction model, and the factor data includes grouping instructions for the grouping of the construction components into each factor of the plurality of factors. The method also includes sending assembly data based on the centralized construction model comprising instructions for completing each factor in the plurality of factors.

### CROSS-REFERENCE TO RELATED APPLICATIONS

This application claims the benefit of U.S. Provisional Application No. 63/114,323, filed on Nov. 16, 2020, U.S. Provisional Application No. 63/114,341, filed on Nov. 16, 2020, U.S. Provisional Application No. 63/114,349, filed on Nov. 16, 2020, U.S. Provisional Application No. 63/114,390, filed on Nov. 16, 2020, U.S. Provisional Application No. 63/114,401, filed on Nov. 16, 2020, U.S. Provisional Application No. 63/114,408, filed on Nov. 16, 2020, U.S. Provisional Application No. 63/114,417, filed on Nov. 16, 2020, U.S. Provisional Application No. 63/114,426, filed on Nov. 16, 2020, U.S. Provisional Application No. 63/114,452, filed on Nov. 16, 2020, U.S. Provisional Application No. 63/114,460, filed on Nov. 16, 2020, U.S. Provisional Application No. 63/114,468, filed on Nov. 16, 2020, U.S. Provisional Application No. 63/114,472, filed on Nov. 16, 2020, U.S. Provisional Application No. 63/114,476, filed on Nov. 16, 2020, U.S. Provisional Application No. 63/114,485, filed on Nov. 16, 2020, U.S. Provisional Application No. 63/114,489, filed on Nov. 16, 2020, U.S. Provisional Application No. 63/114,492, filed on Nov. 16, 2020, U.S. Provisional Application No. 63/115,497, filed on Nov. 18, 2020, and U.S. Provisional Application No. 63/114,755, filed on Nov. 17, 2020. The entire disclosures of each of the above applications are incorporated herein by reference.

### FIELD

The present disclosure relates to methods and systems for integrated component-based construction. More particularly, the present disclosure relates to methods and systems for the coordinating the production process of building projects using centralized networked tools and predetermined components, including design, manufacturing, fulfillment, delivery, installation and post-occupancy.

### BACKGROUND

This section provides background information related to the present disclosure which is not necessarily prior art.

Traditional construction methods and related systems often include the preparation of a design and then the use of general contractors and/or skilled trades people to build the construction project based on the design. The contractors and skilled trades people often possess industry and trade knowledge and skills that enable such individuals to perform the necessary steps to complete the construction project efficiently and adequately to meet various requirements for the project such as price, timing, function, zoning, safety, durability and the like. The building materials used during construction projects using such traditional methods and systems often are sourced from a variety of vendors, suppliers and manufacturers that may have purchasing programs or relationships with the traditional contractors and/or trades people.

These traditional construction methods and systems, however, suffer from problems and drawbacks. For example, such traditional construction methods and systems require the individualized and/or specialized knowledge of the contractors and/or skilled tradespeople. Without such individuals, such as during labor shortages, increases in building demand or in geographic areas without such individuals, construction projects can be difficult to complete. Furthermore, when the availability of individuals with sufficient knowledge and skill is low, the quality, price, durability and safety of construction projects can suffer. Still further, the availability, timing and delivery of construction building materials can be slow, costly and inefficient using traditional supply chains that use traditional building material suppliers, vendors and manufacturers.

In other existing construction methods and systems, pre-fabricated construction projects can allow for all or portions of a construction project to be performed remote from a construction site. Such pre-fabricated construction projects or portions thereof can then be transported from the building location to the construction site. Such pre-fabricated construction methods and systems also suffer from problems and drawbacks. For example, existing pre-fabricated construction methods and systems often allow only for minor variation between construction projects such that the construction projects lack differentiation, personalization and/or the like. Another drawback is that there are limitations on what size, shape, weight and/or configuration can be transported from a building location to a construction site.

Therefore, there exists a need for improved construction methods and systems that address the problems and drawbacks of existing processes.

### SUMMARY

This section provides a general summary of the disclosure, and is not a comprehensive disclosure of its full scope or all of its features.

In some embodiments, the systems and methods of the present disclosure may include a construction system that is coupled to a communication network that permits most if not all aspects of a construction project to be coordinated by a coordination platform. The coordination platform can coordinate the design, permitting, and approvals of a construction project in the early stages. The coordination platform can also connect various stakeholders in the supply chain for a construction project. The various stakeholders can include owners, designers, architects, regulatory agencies, governments, suppliers, fulfillment centers, builders, contractors and the like. The coordination platform can, unlike existing or traditional construction systems and methods, develop a comprehensive construction plan that divides or separates the construction project into various stages or factors. The materials and instructions for each factor can be fabricated and delivered just-in-time to make the entire construction process more efficient and require less specialized knowledge than traditional systems. Furthermore, the construction project can be designed and built using a library of construction components having predetermined characteristics and assembly markings that make the assembly process much easier and more efficient. The coordination platform can connect all stakeholders during construction and even provide coordination and information to subsequent owners of the construction project.

In some embodiments in accordance with the present disclosure, a method of integrated component-based construction is provided. The method may include receiving construction project input data comprising characteristics of a construction project and preparing a centralized construction model based on the construction project input data and on a component library. The component library may include a plurality of construction components having a plurality of predetermined characteristics. The methods may also include determining a construction plan based on the centralized construction model comprising a plurality of factors, each factor in the plurality of factors describing a phase of construction and sending fabrication instruction data and factor data based on the centralized construction model. The fabrication instruction data may include fabrication instructions for the construction components in the centralized construction model, and the factor data may include grouping instructions for the grouping of the construction components into each factor of the plurality of factors. The method may also include sending assembly data based on the centralized construction model comprising instructions for completing each factor in the plurality of factors.

In another aspect, each factor in the plurality of factors may describe a subsequent phase of the construction plan.

In another aspect, the centralized construction model may include a three-dimensional electronic parametric model.

In another aspect, the construction project input data may be received from an affiliate partner via an electronic user interface.

In another aspect, the fabrication instruction data and the factor data is sent to a fulfillment center in a predetermined geographical location relative to a building site for the construction project.

In another aspect, the factor data further may include delivery instructions that indicate a plurality of delivery times when the construction components for each factor in the plurality of factors is to be delivered to a building site.

In another aspect, the plurality of delivery times are different times.

In another aspect, the method may also include re-sending fabrication instruction and factor data after information is received that a previously scheduled factor has been completed.

In another aspect, the method may also include monitoring a status of completion of each factor in the construction plan.

In some embodiments of the present disclosure, a coordination platform is provided. The coordination platform can be configured for coordinating integrated component-based construction projects and may include at least one computing device configured to receive construction project input data comprising characteristics of a construction project and to prepare a centralized construction model based on the construction project input data and on a component library. The component library may include a plurality of construction components having a plurality of predetermined characteristics. The at least one computing device may be further configured to determine a construction plan based on the centralized construction model including a plurality of factors, each factor in the plurality of factors describing a phase of construction. The computing device may be further configured to send fabrication instruction data and factor data based on the centralized construction model. The fabrication instruction data may include fabrication instructions for the construction components in the centralized construction model, and the factor data may include grouping instructions for the grouping of the construction components into each factor of the plurality of factors. The computing device may be further configured to send assembly data based on the centralized construction model comprising instructions for completing each factor in the plurality of factors.

In some embodiments, a user interface for use in coordinating an integrated component-based construction project is provided. The user interface may be configured to permit interaction by a user with a coordination platform and may include a construction plan interface comprising information for a plurality of factors. The factors may include groups of components and assembly instructions for a stage of construction. The user interface may also include a construction model interface that includes one or more tools for interacting and viewing a three-dimensional construction model and a library interface that includes user-selectable interfaces for accessing one or more repositories of information about the construction project.

In one aspect, the one or more repositories of information includes a project renderings interface, a permit interface, a geo interface and a landscape interface.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram illustrating an example construction system in accordance with some embodiments of the present disclosure.

FIG. 2 is a block diagram illustrating an example computing device used in the construction systems of the present disclosure.

FIG. 3 is a block diagram illustrating another example construction system in accordance with some embodiments of the present disclosure.

FIG. 4 is an illustration of an example construction project in accordance with the present disclosure.

FIG. 5 is an illustration of an example construction model of the construction project of FIG. 4 shown in an exploded view.

FIG. 6 is another illustration of the construction model of FIG. 5 shown in another exploded view showing internal and external components.

FIG. 7 is a block diagram illustrating an example construction plan determined by a coordination platform of the present disclosure.

FIG. 8 is a flow chart showing an example method of integrated component-based construction in accordance with some embodiments of the present disclosure.

FIG. 9 is an illustration of an example user interface of a construction application showing a construction plan interface.

FIG. 10 is an illustration of another example user interface of the construction application showing factor detail interface.

FIG. 11 is an illustration of another example user interface of the construction application showing a construction model interface.

FIG. 12 is another illustration of the example user interface of FIG. 11 showing the construction model in an exploded view.

FIG. 13 is another illustration of the example user interface of FIG. 11 showing a layer interface.

FIG. 14 is another illustration of the example user interface of FIG. 11 showing the construction model in a layer view.

FIG. 15 is an illustration of another example user interface of the construction application showing a library interface.

FIG. 16 is an illustration of another example user interface of the construction application showing further functionality and related links.

FIG. 17 shows an example environment in which the construction systems of the present disclosure can operate and interact.

Corresponding reference numerals indicate corresponding parts throughout the several views of the drawings.

### DETAILED DESCRIPTION

Example embodiments will now be described more fully with reference to the accompanying drawings. For purposes of the description hereinafter, it is to be understood that the embodiments described below may assume alternative variations and embodiments. It is also to be understood that the specific articles, compositions, and/or processes described herein are exemplary and should not be considered as limiting. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. The terms “couple,” “coupled,” “operatively coupled,” “operatively connected,” and the like should be broadly understood to refer to connecting devices or components together either mechanically, electrically, wired, wirelessly, or otherwise, such that the connection allows the pertinent devices or components to operate (e.g., communicate) with each other as intended by virtue of that relationship.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

In the present disclosure the singular forms “a,” “an,” and “the” include the plural reference, and reference to a particular numerical value includes at least that particular value, unless the context clearly indicates otherwise. When values are expressed as approximations, by use of the antecedent “about,” it will be understood that the particular value forms another embodiment. As used herein, “about X” (where X is a numerical value) preferably refers to ±10% of the recited value, inclusive. For example, the phrase “about 8” preferably refers to a value of 7.2 to 8.8, inclusive. Where present, all ranges are inclusive and combinable. For example, when a range of “1 to 5” is recited, the recited range should be construed as including ranges “1 to 4”, “1 to 3”, “1-2”, “1-2 & 4-5”, “1-3 & 5”, “2-5”, and the like. In addition, when a list of alternatives is positively provided, such listing can be interpreted to mean that any of the alternatives may be excluded, e.g., by a negative limitation in the claims. For example, when a range of “1 to 5” is recited, the recited range may be construed as including situations whereby any of 1, 2, 3, 4, or 5 are negatively excluded; thus, a recitation of “1 to 5” may be construed as “1 and 3-5, but not 2”, or simply “wherein 2 is not included.” It is intended that any component, element, attribute, or step that is positively recited herein may be explicitly excluded in the claims, whether such components, elements, attributes, or steps are listed as alternatives or whether they are recited in isolation.

The methods and systems of the present disclosure provide integrated, coordinated processes for the construction of building projects that are more efficient, require less specialized knowledge, and can be completed in less time using less resources than existing methods and systems. The methods and systems of the present disclosure may include a centralized coordination platform that includes one or more engines that can allow all stakeholders in the value chain to access, design, plan and perform various steps to produce construction projects. In some examples, the methods and systems of the present disclosure may be used to construct residential building projects. In other examples, the methods and systems of the present disclosure can be used to construction other projects such as commercial or public building projects.

The methods and systems of the present disclosure include improvements to traditional construction processes at all facets of the production process including design, manufacturing, fulfillment, delivery, installation and post-occupancy. The methods and systems can include the use of a centralized coordination platform, networked tools and/or predetermined components as well as networks and communication among various stakeholders. The methods and systems of the present disclosure can resolve problems of traditional processes and systems that include lack of specialized knowledge, restrictions on labor, problems with materials, delivery, waste, inefficiency and the like. The methods and systems of the present disclosure can also allow users to efficiently design and customize a building project in accordance with local zoning requirements. The methods and systems of the present disclosure can also improve logistical problems of traditional systems by reducing the requirements for special equipment and settings. In addition, the methods and systems of the present disclosure can resolve economic issues in traditional systems such as problems of scale. The methods and systems of the present disclosure can allow construction efforts to be easily scaled due to the distribution of capital among the value chain as well as the improvements in efficiency and reduction on skilled labor requirements. The cost of implementing a construction infrastructure is lowered and/or distributed as compared to traditional construction processes and infrastructures.

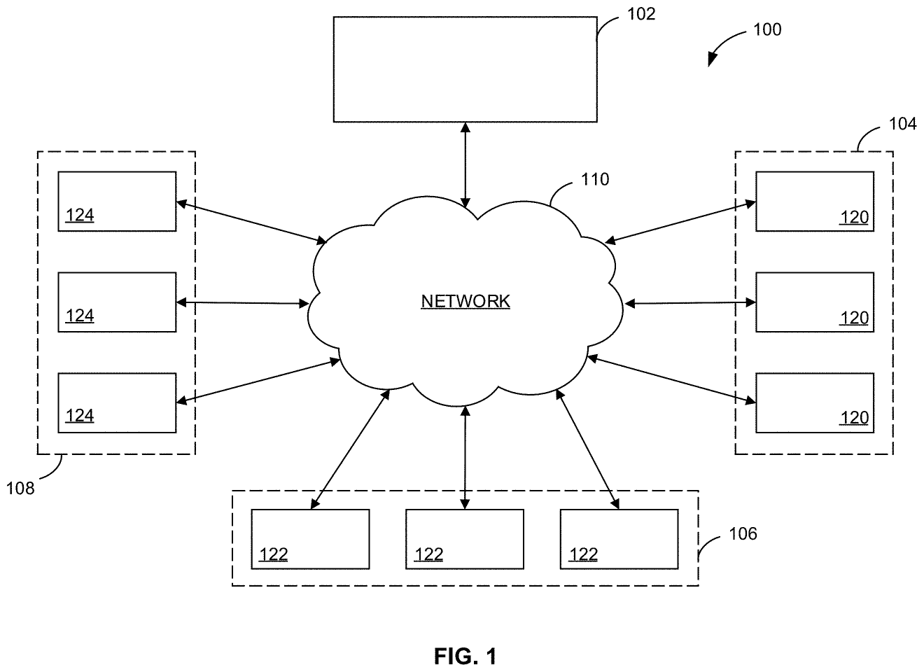

Referring now to FIG. 1, a construction system 100 is shown. In this example, the construction system 100 includes a coordination platform 102, a customer group 104, a fulfillment group 106 and an affiliate group 108. As shown, the various aspects of the construction system 100 can be operatively coupled using a network 110. The network 110 can be any suitable network that allows for the communication and/or exchange of information and data. Various examples of the network 110 include a WiFi® network, a cellular network such as a 3G, 4G, 5G or 6G network, a Bluetooth® network, a satellite network, a wireless local area network (LAN), a network utilizing radio-frequency (RF) communication protocols, a Near Field Communication (NFC) network, a wireless Metropolitan Area Network (MAN) connecting multiple wireless LANs, a wide area network (WAN), or any other suitable network. Network 110 can provide access to, for example, the Internet.

The coordination platform 102, as will be further explained, can include one or more computing devices. The customer group 104, the fulfillment group 106 and the affiliate group 108 can also include one or more computing devices, 120, 122, and 124, respectively. The one or more computing devices of the coordination platform 102 or the computing devices 120, 122, and 124 can be a computer, a workstation, a laptop, a server such as a cloud-based server, or any other suitable device. In some examples, each of the computing devices can be a cellular phone, a smart phone, a tablet, a personal assistant device, a voice assistant device, a digital assistant, a laptop, a computer, or any other suitable device.

In one example, the coordination platform 102 includes one or more servers operated by a construction coordinator. The various stakeholders in the construction process can connect and interact with the coordination platform 102 through the network 110. For example, the customer group 104 can be an individual or developer that may desire to use the services of the construction coordinator that operates the coordination platform 102. The customer group 104 can be an individual client that desires to build a residential home, for example. The customer group 104 can also include building owners that may purchase built homes or other structures that have been previously built using the coordination platform 102. The customer group 104 can connect to the coordination platform 102 to obtain information regarding a construction project that is in the planning stages, to obtain information regarding a construction project that is in progress and to obtain legacy maintenance and historical information regarding a construction project that was previously built using the coordination platform 102. In still other circumstances, the customer group 104 can obtain other information regarding a construction project connection to the coordination platform 102.

The affiliate group 108 can be one or more service providers that can also connect to the coordination platform 102. The affiliate group 108 can include, for example, designers, builders, contractors or other service providers that can assist a customer from the customer group 104 to plan, build, repair or maintain a construction project. For example, an entity in the affiliate group may be a residential builder that can connect to the various tools and engines in the coordination platform 102 to design a home. The affiliate group may obtain training from the operator of the coordination platform 102 to perform such services for the customer. After a home has been designed through the tools and interfaces of the coordination platform 102, the coordination platform 102 can build a centralized construction model and determine a construction plan. The coordination platform 102 can also determine fabrication data and factor data that describes components and the various steps required to complete the construction project.

The fulfillment group 106 can also connect to the coordination platform 102. The fulfillment group 106 can include other vendors, suppliers, and/or manufacturers that can supply components, materials and other products in coordination with the construction plan that is determined by the coordination platform 102. As will be further described, the coordination platform 102 can provide fabrication instruction data and factor data to the fulfillment group 106 via the network 110. The fabrication instruction data can, for example, include information for one of the manufacturers in the fulfillment group 106 to fabricate one or more components that will be used to build the construction project that was designed by one of the affiliates in the affiliate group 108. Each of the fulfillment centers in the fulfillment group may be, for example, different fulfillment centers located in different geographic locations to service a local region.

As can be appreciated, multiple construction projects can be at different stages of development, construction or maintenance at any particular time. Thus, multiple stakeholders may be accessing and communicating with the coordination platform 102 regarding a particular construction project simultaneously. In other instances, multiple stakeholders may be accessing and communicating with the coordination platform 102 for different construction projects in the same geographical region or in different geographic regions.

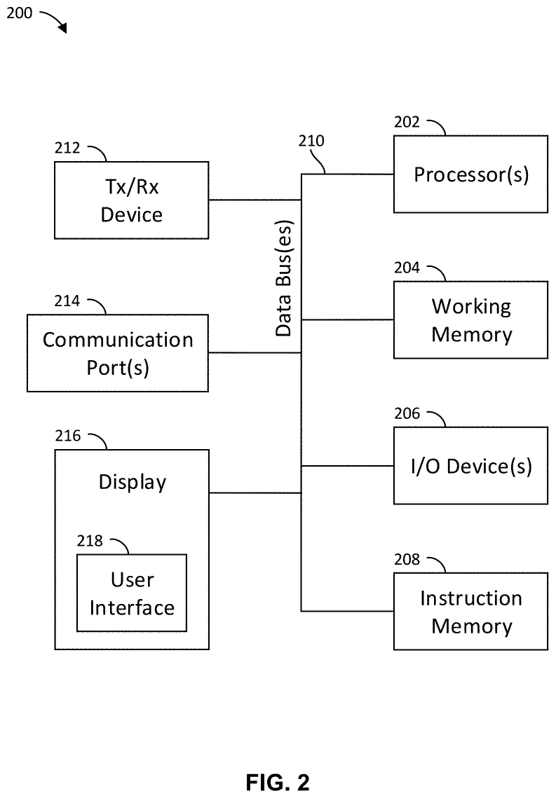

As shown in FIG. 2, each of the computing devices (e.g., servers, computers, workstations, mobile devices, etc.) may include the various elements shown. The various elements shown in FIG. 2 and described below can enable the computing devices of the coordination platform 102 and the computing devices 120, 122, 124 to communicate with each other (either directly or indirectly) and to enable the various methods described herein. For the sake of brevity, FIG. 2 is described relative to the coordination platform 102. It should be appreciated, however, that the elements described can be included, as applicable, in the computing devices 120, 122, 124.

The computing device 200 can include one or more processors 202, working memory 204, one or more input/output devices 206, instruction memory 208, a transceiver 212, one or more communication ports 214, and a display 216, all operatively coupled to one or more data buses 210. Data buses 210 allow for communication among the various devices. Data buses 210 can include wired, or wireless, communication channels.

Processors 202 can include one or more distinct processors, each having one or more cores. Each of the distinct processors can have the same or different structure. Processors 202 can include one or more central processing units (CPUs), one or more graphics processing units (GPUs), application specific integrated circuits (ASICs), digital signal processors (DSPs), and the like.

Processors 202 can be configured to perform a certain function or operation by executing code, stored on instruction memory 208, embodying the function or operation. For example, processors 202 can be configured to perform one or more of any function, method, or operation disclosed herein.

Instruction memory 208 can store instructions that can be accessed (e.g., read) and executed by processors 202. For example, instruction memory 208 can be a non-transitory, computer-readable storage medium such as a read-only memory (ROM), an electrically erasable programmable read-only memory (EEPROM), flash memory, a removable disk, CD-ROM, any non-volatile memory, or any other suitable memory.

Processors 202 can store data to, and read data from, working memory 204. For example, processors 202 can store a working set of instructions to working memory 204, such as instructions loaded from instruction memory 208. Processors 202 can also use working memory 204 to store dynamic data created during the operation of the computing device 200, such as during the operation of the coordination platform 102. Working memory 204 can be a random access memory (RAM) such as a static random access memory (SRAM) or dynamic random access memory (DRAM), or any other suitable memory.

Input-output devices 206 can include any suitable device that allows for data input or output. For example, input-output devices 206 can include one or more of a keyboard, a touchpad, a mouse, a stylus, a touchscreen, a physical button, a speaker, a microphone, or any other suitable input or output device.

Communication port(s) 214 can include, for example, a serial port such as a universal asynchronous receiver/transmitter (UART) connection, a Universal Serial Bus (USB) connection, or any other suitable communication port or connection. In some examples, communication port(s) 214 allows for the programming of executable instructions in instruction memory 208. In some examples, communication port(s) 214 allow for the transfer (e.g., uploading or downloading) of data, such as construction designs, centralized construction model, fabrication data, factor data and the like.

Display 216 can display a user interface 218 and/or multiple user interfaces 218. User interfaces 218 can enable user interaction with the coordination platform 102. For example, user interface 218 can be a user interface that allows an affiliate to design a construction project. In another example, the user interface 218 may be located on a mobile device of a customer. In such an example, the customer can interact, communicate, control and/or modify different features or parameters of the centralized construction model that may be located in the coordination platform 102. In yet another example, a user interface 218 may be located on a workstation in a fulfillment center. The user interface 218 can allow the fulfillment center to receive fabrication data to create components to be used in the construction project. In some examples, a user can interact with user interface 218 by engaging input-output devices 206. In some examples, display 216 can be a touchscreen, where user interface 218 is displayed on the touchscreen.

Transceiver 212 allows for communication with a network, such as the communication network 110 of FIG. 1. For example, if communication network 110 of FIG. 1 is a cellular network, transceiver 212 is configured to allow communications with the cellular network. In some examples, transceiver 212 is selected based on the type of network 110 coordination platform 102 will be operating in. Processor(s) 202 is operable to receive data from, or send data to, a network, such as communication network 110 of FIG. 1, via transceiver 212.

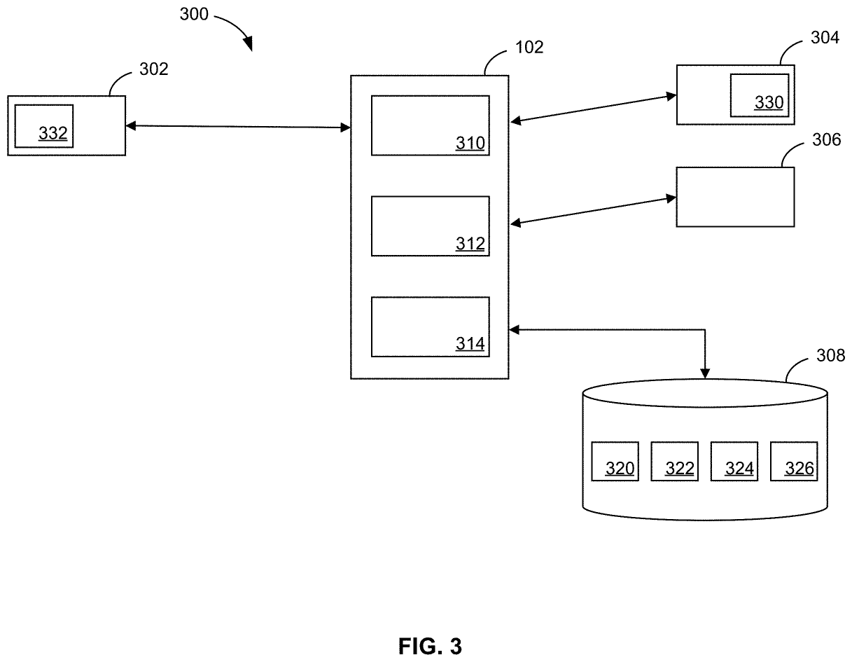

Turning now to FIG. 3, one example coordination platform 102 is shown. As can be seen, the coordination platform 102 is operatively coupled to a customer computing device 302, an affiliate computing device 304, a fulfillment computing device 306 and a database 308. While not shown, the coordination platform 102, the customer computing device 302, the affiliate computing 304, the fulfillment computing device 306 and the database 308 can be coupled using any suitable means such as by network 110 (FIG. 1). While only one of each of the customer computing device 302, the affiliate computing device 304, the fulfillment computing device 306 and the database 308 is shown. It should be appreciated that multiple such devices can be used in the construction system 300 as shown in the construction system 100 of FIG. 1.

The coordination platform 102 can be implemented on one computing device or may be implemented on multiple computing devices that may be coupled together. The coordination platform 102 may include a single processor or multiple processors that can be operable to implement software or other executable instructions to provide the functionality as described in this disclosure. In the example shown, the coordination platform 102 includes a data acquisition engine 310, a construction model engine 312 and a construction plan engine 314. In other examples, the coordination platform can include more or less engines, modules or other packages and tools to provide the functionality described.

The data acquisition engine 310 may allow the coordination platform 102 to obtain or receive data and/or information from other sources such as from the customer computing device 302, the affiliate computing device 304, the fulfillment computing device 306 and/or the database 308. The data acquisition engine 310 may also be operable to send data and/or information to these other devices and repositories. The data acquisition engine 310 can use, for example, application protocol interfaces (APIs) to facilitate the exchange of data and information from other sources. The data acquisition engine 310 may also transform, normalize, truncate or otherwise process data that is received from other sources in order that such information is compatible or usable with the coordination platform 102. Similarly, the data acquisition engine 310 may process the data or information that it sends to other sources to make the data and/or information usable or for the efficient exchange of such information.

The construction model engine 312 allows the coordination platform 102 to build and use a centralized three-dimensional (3D) model of a construction project. The centralized 3D model can include information, for example, that allows the coordination platform 102 to determine the necessary components and building materials that are required to complete the construction project. The centralized 3D model, for example, can be a detailed parametric model that can be manipulated to extract building information and also can be easily changed or modified to suit the needs of the customer.

The construction model engine 312 can build or manipulate the centralized 3D construction model using various computer-aided drafting methods and interfaces. In some examples, the operator of the coordination platform 102 can provide software, tools and/or interfaces to affiliates that can work with customers to design and specify a construction project. Such software, tool and/or interfaces can be installed or otherwise utilized via a cloud-based system using the affiliate computing devices 304. In the context of residential building projects, a customer may contact an affiliate partner of the operator of the coordination platform 102. The affiliate may be a designer, architect, or other service provider that may provide design services. The customer and the affiliate can work together to create a design or set of specifications for a residential home that the customer desires to have built. The design may include size, appearance, location, internal amenities, layout and other information to describe various aspects of the residential building project. This information can be sent or otherwise provided to the coordination platform 102 from the affiliate computing device 304.

The affiliate computing device 304 can include a design tool 330, for example. The design tool 330 can be a software package, a design interface or other interface that can allow the affiliate to access a remote (e.g., cloud-based) design application.

Once the design information has been provided to the construction model engine 312 or been obtained by the construction model engine 312, the construction model engine 312 can create the centralized 3D construction model. The construction model engine 312 can automatically create the centralized 3D construction model in some examples. In other examples, the information that is provided by the affiliate and/or the affiliate computing device 304 can be used by professional model designers to build the centralized 3D construction model. The 3D construction model, for example, can be built using a suitable design package such as Revit. In other examples, other suitable packages, software or tools can be used. In some examples, the 3D construction model is a Building Information Modeling (BIM) model. In other examples, other models can be used.

After the construction model is built, the centralized 3D construction model can be stored either in the coordination platform 102 or in the database 308. In the example shown, the centralized 3D construction model 320 is stored in the database 308. As such, the coordination platform 102 can access, use and modify the centralized construction model 320.

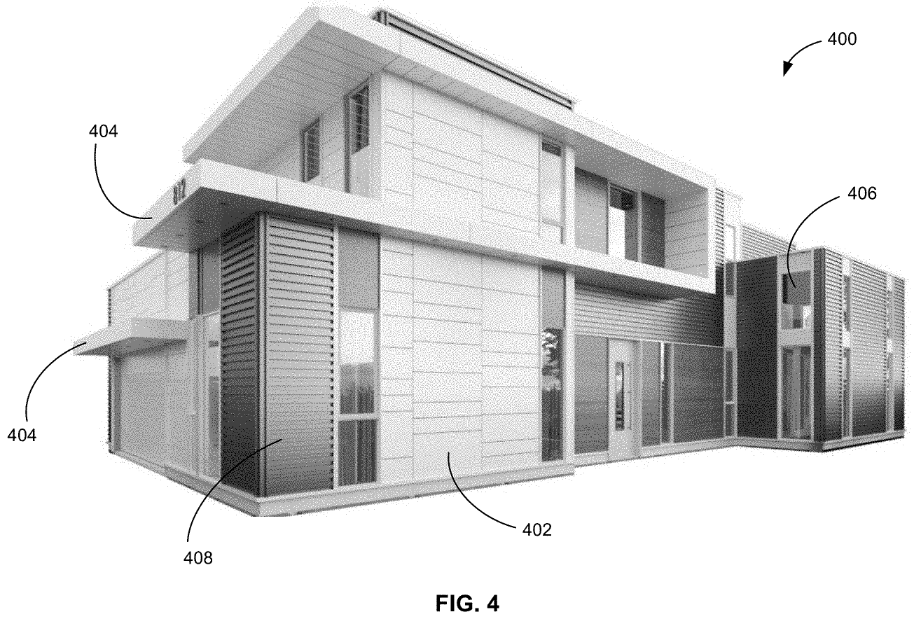

As shown in FIG. 4, an example construction project 400 can be a residential home. The construction project 400 can also be other types of construction projects such as commercial or public buildings or structures. In this example, the construction project 400 can be built using integrated component-based construction (ICBC) technology and components. Integrated component-based construction includes technology, methods and materials that may include a library of components and building processes that standardizes the fabrication and assembly of the construction project 400. Elements of ICBC technology can include standard components, non-standard components and common products.

Standard components can include building components that are proprietary components to the operator of the coordination platform 102. In one example, the standard components can include a library of standard components. The standard components do not change and are typically used in every construction project. There can be more than 100 standard components used on one example of the coordination system 100. Examples of standard components include coping, wall bases, doors, windows, corner trims, rebar matts. Standard components are typically used in the same manner for the same function in various building projects; thus could be inventoried.

Non-standard components are components that are principally the same but may have different design parameters such as different dimensions or different aspects specific to a particular construction project. Non standard components have a unique ID number. The non-standard components may be unique to a specific building project. Because of some of the dimensional characteristics, they often cannot be used in other circumstances. The non-standard components may have to be produced specifically for a building project. However, their family gives them the same consistent characteristics, only with certain dimensional differences. Examples of non-standard components include wall panels, Proto Core, Face Frames, cladding panels, stairs, sill plates, ledger boards, etc.

Common products are products that are commonly used building materials used in many constructions projects. These materials include fasteners, adhesives, sealers, windows and the like that are commonly used in construction projects. ICBC technology and methods are further described in co-pending U.S. Patent Application No. TBD, entitled Integrated Component-Based Construction Components and Related Methods filed on Nov. 16, 2021. The entirety of this application is incorporated herein by reference. As described therein, the components used in ICBC methods can be printed, etched or otherwise marked with assembly information that indicates how the components are attached together and/or fastened in the construction project. For example, sill plates and/or walls can arrive to the construction site with markings that indicate how the sill plates are attached to the foundation and/or to the walls of the construction project. Such markings can include, for example, markings that show where adjacent construction components are joined, where electrical or plumbing components may be attached or guided through the components or the like. The pre-marking of the ICBC components allows the components to be assembled with fewer instructions, plans, oversight and construction knowledge than existing construction methods that may rely on highly trained construction professionals. In addition, the pre-marking of the components can reduce the likelihood of errors during the construction process. Still further, the limitation on available components can make the design process much easier that if the options are endless.

Referring back to FIG. 4, the construction project 400 can include for example a plurality of standard components such as wall panel 402 and siding 408. The construction project 400 may also include non-standard components such as exterior extensions 404. As can be appreciated, the exterior extensions 404 can utilize common elements such as cross-sectional shapes, supports for extending the extensions away from the exterior of the construction project 400 and the like, but may have different lengths (i.e., distances along the exterior of the construction project 400). The construction project 400 can also include common products such as windows 406.

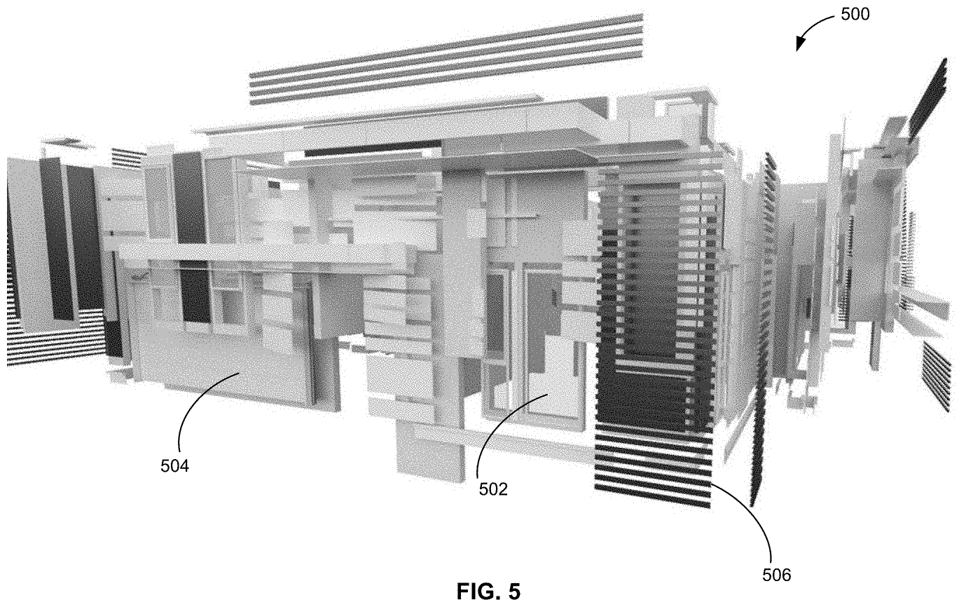

The construction project 400 may be represented by a centralized construction model. The centralized construction model can be a 3D parametric model that includes each of the components and/or products that may be used to build the construction project 400. As shown in FIG. 5, the construction model may allow a user to view and/or extract the information regarding the various components that are used to build the construction project 400. As shown in FIG. 5, the construction model 500 can be viewed in an exploded format that can separate the assembled project into the various components and products. A few examples of the components and products of the construction model 500 are shown in FIG. 5. As shown, the construction model 500 can include information regarding door 502, wall 504, cladding 506 and the like.

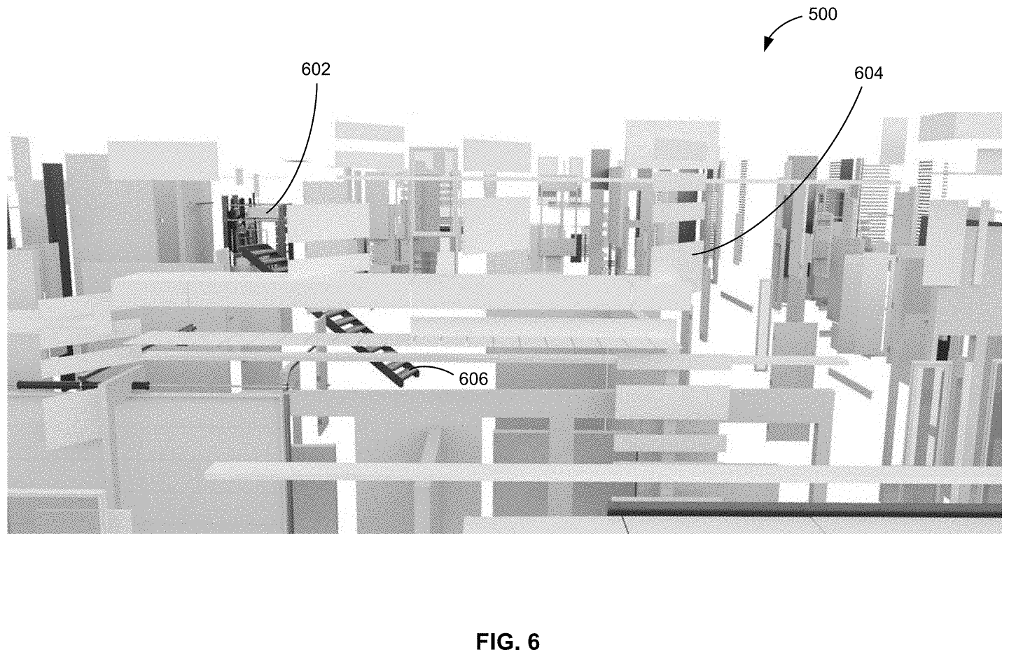

As shown in FIG. 6, the construction model 500 can be further separated and/or viewed in an exploded format to view not only the exterior components and/or products but also the interior components and/or products such as core 602, interior wall 604, staircase 606 and the like. More details of the core 602 and related embodiments are described in U.S. Pat. Appl. No. TBD entitled CENTRALIZED CORE AND NODE SYSTEM FOR CONSTRUCTION PROJECTS filed on Nov. 16, 2021, the contents of which are hereby incorporated by reference in its entirety.

Referring back to FIG. 3, the coordination platform 102 may also include the construction plan engine 314. The construction plan engine 314 can operate to determine a construction plan for the construction project. The construction plan can include information and data for the components used to build the construction project as well as fabrication and/or assembly data used to build the construction project.

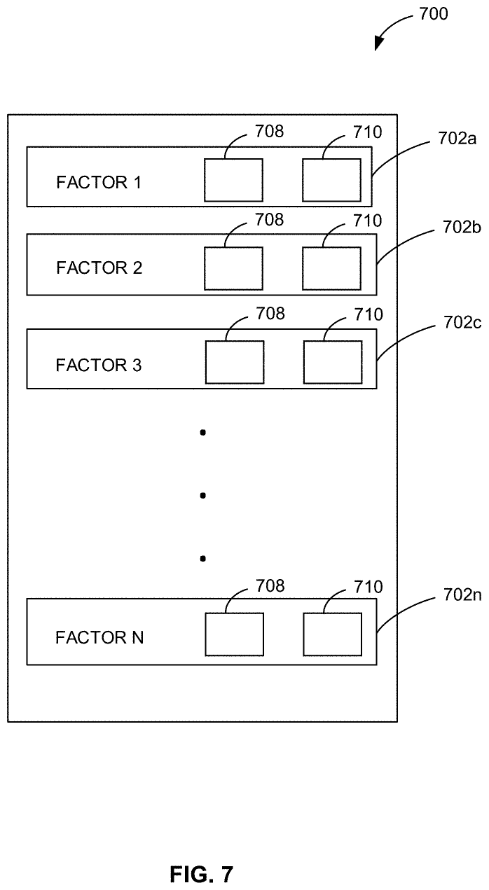

As shown in FIG. 7, the construction plan 700 can include, in one example, a plurality of factors 702a, 702b, 702c . . . 702n. A factor 702 is a grouping of components, materials and tasks that are performed at a predetermined time during the completion of a construction project. The construction plan 700 can include any number of factors 702 that may be required for completion of a particular construction plan. Factors 702 can be understood to be particular delineated step of the construction process. Example factors 702 can include for example, Project Kick-off, Footing, Slab, Core, 1st Floor Structure, 2nd Floor Structure, 3rd Floor Structure, Interior Walls and Ceiling, Roofing, Weatherproofing, Interior Doors, Electrical Boxes and Cans, Garage Door, Rough Plumbing, Rough HVAC, Fire Sprinklers, Wiring Electrical, Coping and Wall Base, Arch Projections, Exterior Trim, PVC Cladding, Exterior Painting, Metal Cladding, Accent Cladding, Insulation and Drywall, Tile Work, Interior Painting, Casework and Cabinets, Counter Top, Finish Mechanical, Electrical and Plumbing, Interior Finishes, Appliances, Finish Sprinkler Heads, and Close-out. In other examples, factors 702 can include other steps or stages of construction projects. One step can include the installation of electrical components. Further detail regarding electrical systems that can be incorporated into the construction methods and systems of the present disclose can be found in U.S. Pat. Appl. No. TBD entitled INTEGRATED WHOLE HOUSE ELECTRICAL SYSTEM filed on Nov. 16, 2021, the contents of which is hereby incorporated by reference in its entirety.

Each of the factors 702 above, can include multiple types of information. Each of the factors 702 may include, for example, fabrication information/data 708, and/or assembly information/data 710. The fabrication data 708 can include information that can allow suppliers and/or fulfillment centers to manufacture and/or acquire the materials that are required for a particular factor 702. The fabrication data 708 can include dimensions, materials, quantities, sizes, relationships between components and other information. The fabrication data 708 can also include marking data that indicates to the fulfillment centers and/or suppliers the markings that are to be included on the ICBC components. The assembly data 710 can include information for the construction professionals that describes how the components and products are to be assembled together at the construction site.

Each factor can include its own fabrication data 708 and assembly data 710. In this manner, the components and assembly information can be created and then delivered to construction site for each factor 702 individually rather than entire loads or amounts of construction materials being shipped and/or delivered to a construction site. This type of step-by-step fabrication, delivery and assembly can simplify the construction process, reduce the likelihood of materials being wasted, stolen or being damaged. Once each factor is completed at the construction site, the next factor 702 can be initiated and then completed. Once all the factors 702 are completed, the construction project is complete.

As discussed above, the construction plan engine 314 can determine the construction plan like the construction plan 700 previously described. The construction plan engine 314 can use the centralized construction model 320 to determine the various factors 702a to 702n that may be required for a particular construction project. The construction plan engine 314 can extract the components for each stage of construction (i.e., each factor 702) and then group the components together for each factor. Factor data 322, fabrication data 324 and assembly data 326 can be stored, for example, database 308 to be accessed, used and/or displayed by various elements of the construction system 300 (FIG. 3).

As further shown in FIG. 3, the customer computing device 302 can include a construction application 332. The construction application 332 can be an app either stored locally or accessed via the customer computing device 302 that can be coupled to the coordination platform 102. The construction application 332 can have various functionality, user interfaces and the like to allow a customer to view information such as construction model 320, factor data 322, fabrication data 324, assembly data 326 and/or the construction plan. The construction application 332 can also allow the customer to input information, submit changes or requests for the construction project and/or track the progress of the completion of the project. The construction application 332 can also be used by other stakeholders in the construction system 300 such as suppliers, fulfillment centers, affiliates and the like.

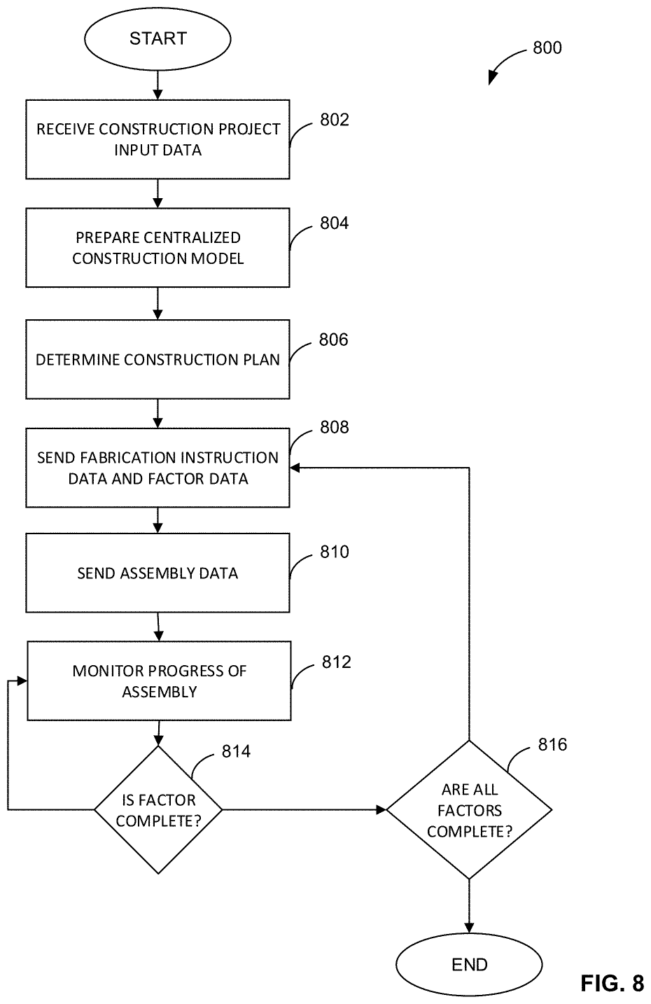

Turning now to FIG. 8, an example method of integrated component-based construction (ICBC) is shown. The example method 800 can be implemented using a construction system such as the construction systems 100, 300 previously described. In other instances, other construction systems can be used as well as variations of the construction systems previously described. In one example, the method 800 can be implemented by the coordination platform 102. For the sake of brevity, the method 800 is described relative to the coordination platform 102 and the construction systems 100, 300 previously described. It should be appreciated, however, that the method 800 and/or aspects thereof can be implemented by other systems and variations as known to one of ordinary skill in the art.

The method 800 may begin at step 802. At step 802, construction project input data is received. The construction project input data may be received by the coordination platform 102. The data acquisition engine 310 may obtain the construction project input data from a customer or from an affiliate. In one example, a customer may engage the services of an affiliate to assist in the design and development of a construction project such as a residential home. The customer can provide details of the characteristics of the residential home that is desired. The affiliate (e.g., real estate professional, architect, designer, contractor, builder, etc.) may then use the design tool 330 (FIG. 3) to design the residential home. The coordination platform 102 can then obtain or receive the construction project input data in the form of the design that is created by the affiliate using the design tool 330.

In some instances, the design tool 330 may be configured to access a library of ICBC components. The design tool 330 can be limited or include other pre-configured settings and parameters such that the design of the construction project utilizes the ICBC components including the standard components, non-standard components and common products previously described. In this manner, the design of the construction, and thus the construction project input data, can include characteristics of the construction project that may include characteristics of the ICBC components such as quantity, size, dimensions, etc. of such components.

In other instances, the customer and/or the affiliate may input construction project input data using a construction application that can be operated locally or via the cloud on a mobile computing device such as a smart phone. The construction application, an example of which is further described below, may include a construction project design user interface that can allow the customer and/or the affiliate to input characteristics of the construction project (e.g., size, number of bedrooms, number of bathrooms, number of floors, etc.). This information can then be retrieved and/or sent to the coordination platform 102 at step 802.

At step 804, a centralized construction model is prepared. The construction model engine 312 may prepare the centralized construction model. In some examples, the centralized construction model can be prepared automatically using pre-configured libraries of ICBC components and using predetermined floor plans and schematics that may be stored in database 308. For example, the construction model engine 312 may automatically choose one or more predetermined construction models from a repository of predetermined construction models based on the construction project input data received at step 802. In other examples, the construction model engine 312 can be trained machine learning model that can be trained to automatically build a construction model based on the various characteristics that a customer and/or affiliate indicates is desired and based on the limitations of a building site and/or local building codes or requirements.

In still other examples, the construction model can be created by a design professional using the construction model engine 312 that may include computer-aided drafting applications or other suitable tools that allow the design professional to create the construction model using a library of ICBC components and other materials.

At step 806, a construction plan is determined. As previously described, the construction plan may include fabrication data, factor data and assembly data. The construction plan can be determined by construction plan engine 314, for example. The construction plan engine 314 can extract components and other materials that are needed to build the construction project from the construction model previously prepared at step 804. The components and other materials can then be grouped into the appropriate factors based on the steps required to build the construction project.

At step 808, the fabrication data and the factor data can be sent to a supplier and/or fulfillment center. In one example implementation of the construction system 100, the coordination platform 102 is operated by a centralized construction operator and various fulfillment centers are operated by supplier partners at various geographic locations to serve these local geographic locations. The coordination platform 102 can include restrictions on the distance from which a fulfillment center can be located relative to a building site. One reason for such a geographic restriction is that the fulfillment centers must continually fabricate, bundle and deliver materials and components just-in-time to take advantage of the improvements of the coordination platform 102.

The fulfillment centers can possess the necessary fabrication equipment such as extruders, stamping equipment, printing equipment, molding equipment, machine shops, assembly lines, saws, CNC machines, optimizers, etc. as well as shipping and receiving centers. The coordination platform 102 can send the fabrication data and the factor data to the fulfillment center computing device(s) 306. The fabrication data and the factor data can include the information required for the fulfillment center to fabricate, manufacture, assemble, bundle and ship the required materials for each factor (i.e., for each stage of construction) to the customer's building site. The fabrication data can include, for example, a size, shape, length, cut list for each ICBC component that may be used in a particular factor. The fabrication data can also include information regarding how each component fits or is assembled to adjacent or neighboring components. The fabrication data can include this information so that markings can be placed (e.g., by etching, printing, or otherwise marking) on the ICBC components at the fulfillment center(s).

At step 810, assembly data can be sent by the coordination platform 102. The assembly data can detail instructions that can be used by construction personnel at the building site to assemble the components and materials for a particular factor. The assembly data can detail, for example, how walls are to be fastened together, how a foundation is to be formed, and/or how exterior cladding is to be attached to the exterior of the structure. The coordination platform 102 can send the assembly data to an affiliate partner that may be performing the assembly services for the customer. In other instances, the assembly data can be sent to a data repository (e.g., database 308) that can be accessed or retrieved by customers, affiliates or others using customer computing device(s) 302 or affiliate computing device(s) 304, for example.

At step, 812, the progress of assembly of the construction project can be monitored. In one example, the coordination platform 102 can monitor the progress of the assembly by reviewing and/or considering updates and/or other information that is provided to the coordination platform 102 by the fulfillment centers and/or the affiliates. For example, when the fabrication and bundling of the ICBC components and other materials is complete, the fulfillment centers can provide information to the coordination platform 102 that such actions are complete. The fulfillment centers can also provide information that such components and materials are shipped and/or have been delivered to a building site. The affiliates (e.g., contractors, builders, etc.) can also provide information to the coordination platform regarding the completion of various tasks that may be included in the assembly data provided at step 812. The builders at a building site can indicate to the fulfillment center when they are ready for delivery of components and/or materials for the next factor in the construction plan. The coordination platform 102 can receive such inputs or information to monitor the progress of the assembly of the construction project.

At step 814, it is determined if a factor is complete. The coordination platform 102 can, for example, consider the information received from the fulfillment centers and/or from the affiliates to determine if a factor is complete. A factor can be determined to be complete, for example, when all tasks listed or provided in the assembly data is indicated as being complete by the fulfillment centers and/or the affiliates.

If the coordination platform 102 determines that a factor is complete, the method 800 can move to step 816. If the coordination platform 102 determines that a factor is not complete, the method 800 returns to step 812 wherein the coordination platform 102 continues to monitor the information received from the fulfillment centers and/or from the affiliates.

At step 816, it is determined whether all factors are complete. The coordination platform 102 can, for example, compare the completed factors to the construction plan. If the coordination platform 102 determines that all factors of the construction plan are complete, the construction project is complete and the method ends. If the coordination platform 102 determines that not all factors are complete, the method 800 can return to step 808. At step 808 in this circumstance, the coordination platform can send fabrication data and factor data to the fulfillment center(s) for the next factor in the construction plan. The method can then continue to steps 810 through 816 to complete each factor in the construction plan.

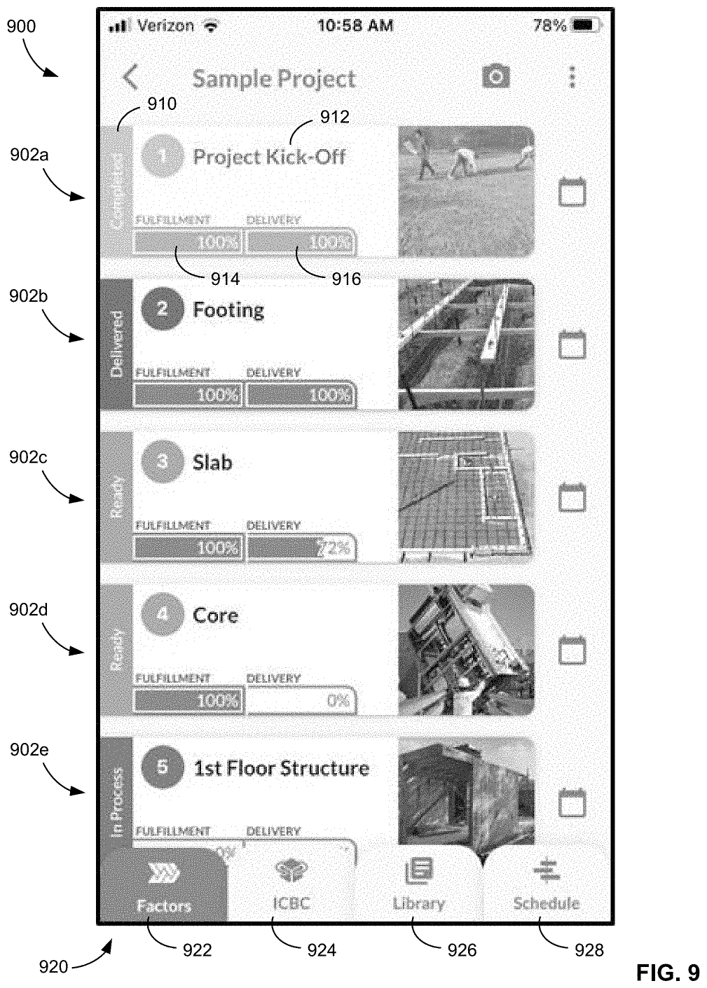

FIGS. 9-16 include screenshots from an example construction application. The construction application can be similar to the construction application 332 described above with reference to FIG. 3. The construction application can be implemented as a locally stored application or as a mobile application that can be accessed by a suitable computing device such as a smartphone, tablet, laptop, or the like. The construction application can allow a customer, affiliate, fulfillment center, or other stakeholder/user to access, view and input information or otherwise interact and communicate with the coordination platform 102.

FIG. 9 depicts an example construction plan interface 900 of a construction application. The construction application can include one or more tabs 920. In this example construction application, the application include four tabs that include factor tab 922, ICBC tab 924, library tab 926 and schedule tab 928. The tabs 920 are user-selectable and when a user selects one of the tabs 920 information regarding various aspects of the construction process can be viewed and interacted with by a user. As shown in FIG. 9, the factor tab 922 is highlighted and has been selected. When the factors tab 922 is selected, the construction plan interface 900 can be displayed. The construction plan interface 900 can include one or more factor interfaces 902. Each of the factor interface 902a to 902n lists each factor that has been determined by the coordination platform 102 and is included in the construction plan.

Each of the factor interfaces 902 can display information regarding a particular factor in the construction plan. Each factor interface 902 can include, for example, a completion indicator 910, a factor name 912, a fulfillment status indicator 914 and a delivery status indicator 916. The completion indicator 910 can indicate a state of completion in the interface 900. As shown, the completion indicator 910 can show status such as completed, delivered, ready, in process, etc. As can be appreciated, the completion indicator 910 updates as information is received regarding status of the various steps to fabricate components, deliver components and assemble components. Various other words, colors and indicators can be used to indicate a status of completion for each factor.

The fulfillment status indicator 914 can indicate a status of the fabrication and/or supply of components for a particular factor. As previously described, the ICBC components used in a factor are obtained or fabricated by fulfillment centers in response to receiving fabrication data from the coordination platform 102. The fulfillment status indicator 914 can show a status of completion of such components, products and materials. In the example shown, the fulfillment status indicator 914 is displayed as a percentage of completion. In other examples, other words, colors, bars, or other indicators can be used.

The delivery status indicator 916 displays a status of the delivery of the components, products and materials to the building site. In the example shown, the delivery status indicator 916 is displayed as a percentage of completion. In other examples, other words, colors, bars, or other indicators can be used.

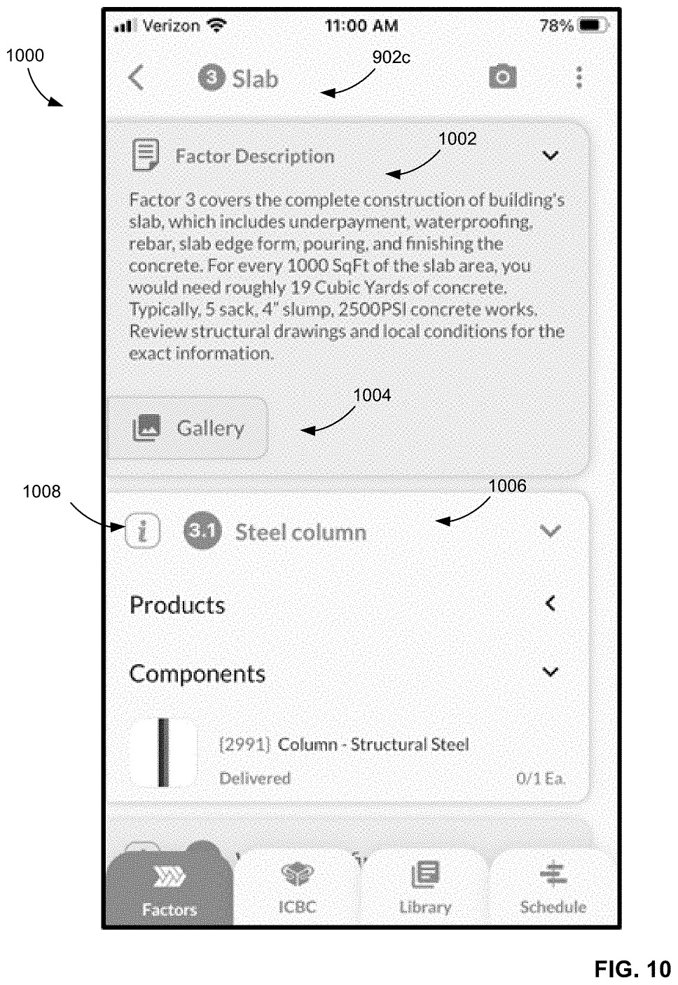

As shown in FIG. 10, the construction application can also include a factor detail interface 1000. The factor detail interface 1000 can be displayed when a user selects one of the factors 902 of construction interface 900. In the example shown, the detail of factor number 3 “Slab” is displayed. It should be appreciated that a similar factor detail interface can be displayed when any one of the factors 902 is selected by a user.

The factor detail interface 1000 can include more detailed information for any one of the factors 902 that is in the construction plan. In the example shown, the factor detail interface 1000 includes factor description 1002, gallery 1004, component detail interface 1006 and instruction interface 1008. The factor description 1002 can provide information regarding the selected factor 902 and can provide references to further information for the factor such as to other drawings, specifications and instructions that may be available in other locations on the construction application such as in the library tab 926. The instruction interface 1008 is a selectable interface. When selected by a user, the instruction interface 1008 can display or deploy instruction specific to the stage of the factor. In the example shown, factor 3.1 is shown that translates to factor 3, stage 1.

The gallery 1004 can be selected to view photos, images, renderings or other items that may have been uploaded to the coordination platform 102 and/or captured by a user. As shown, the factor detail interface 1000 can also include a camera tool to allow the user to capture images of various stages or aspects of the factor 902 of interest.

The component detail interface 1006 include information regarding the various components that used and/or allocated into the factor 902. In the example show, the factor 902c “Slab” includes a steel column as a component. The component detail interface 1006 can identify the component and a delivery status of each component. The component detail interface 1006 can also include information and status for other products or materials that are allocated to the factor 902.

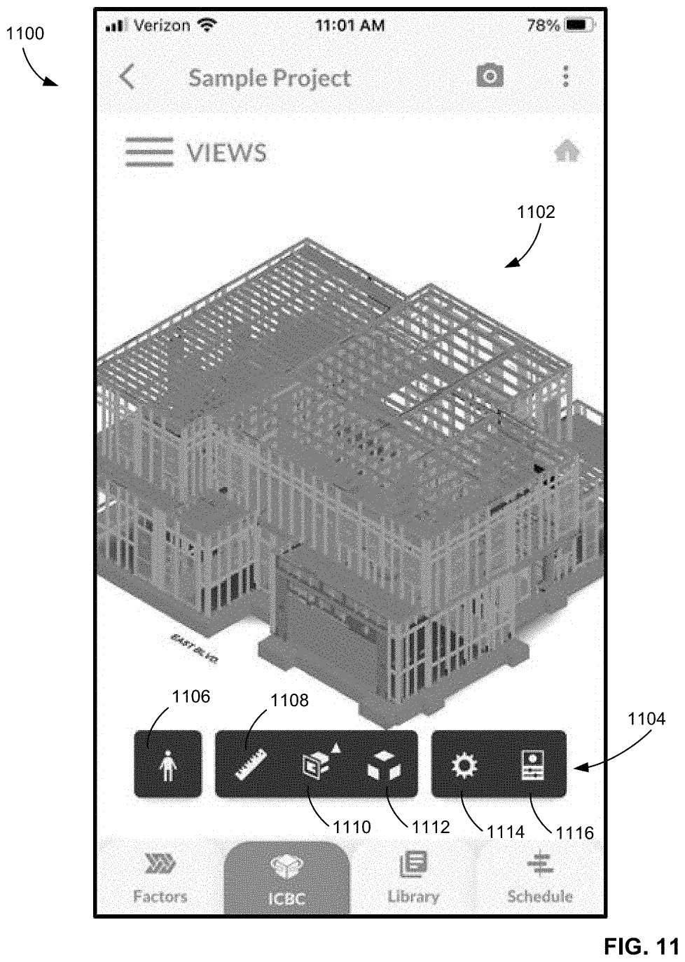

Turning now to FIG. 11, a construction model interface 1100 is shown. The construction model interface 1100 can be shown, for example, when the ICBC tab 924 is selected in the construction application. The construction model interface 100 can display the construction model 1102 and a toolbar 1104. The construction model 1102 can be displayed and then manipulated or otherwise interacted with using either the touchscreen or via the toolbar 1104. For example, a user can zoom, rotate, explode, measure, and select various standard views of the construction model 1102. In the example shown, the toolbar 1104 includes a view selector 1106, a measuring tool 1108, a sectioning tool 1110, an exploding tool, settings selector 1114 and an appearance selector 1116. These various tools allow the user to manipulate and interact with the construction model 1102. In some examples, each component shown in the construction model 1102 can be isolated and identified. Each component can be identified by a Component Identification Number (CID). Such CIDs are critical for identifying non-standard components during the construction process. The components can be marked with a QR code and such information can be isolated and retrieved using the construction model interface 1102. This information can be used to track a component from design, to fabrication, to packaging, to delivery and to installation.

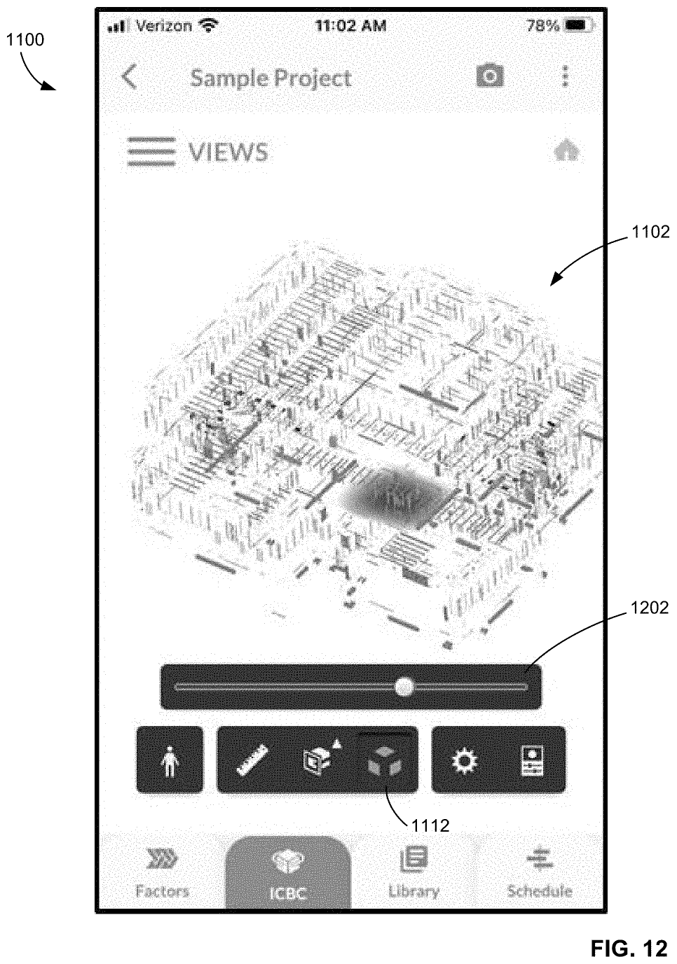

As shown in FIG. 12, the construction model interface 1102 is shown that has been used to display an exploded view of the construction model 1102. In this example, the exploding tool 1112 has been selected by the user. The selection of the exploding 1112 causes a slider bar 1202 to appear that allows the user to explode the components of the construction model 1102 apart so that individual components and the interaction/assembly of the components can be viewed by the user.

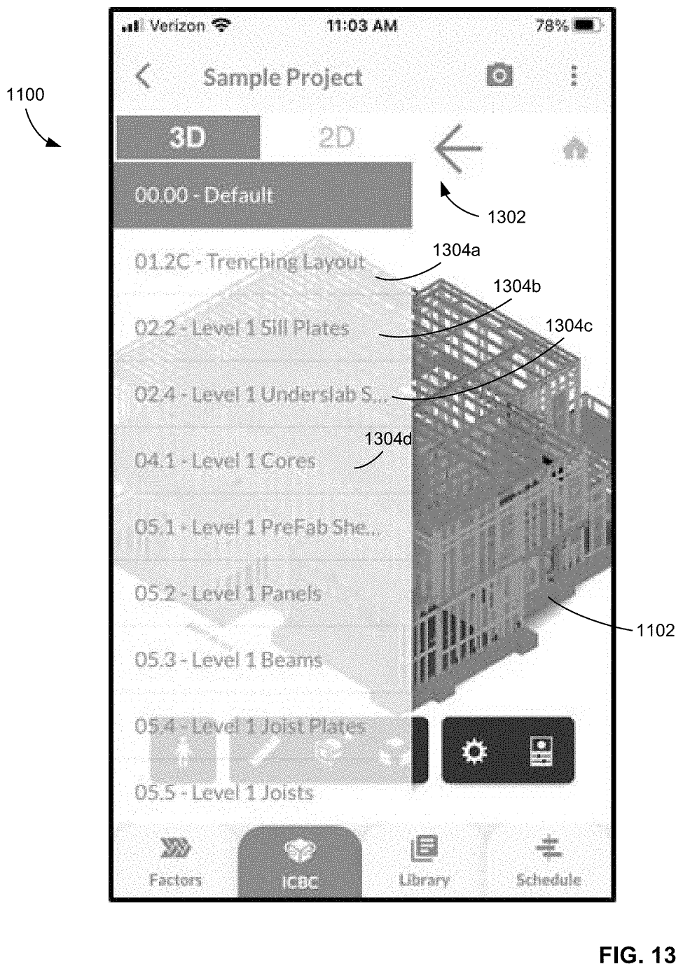

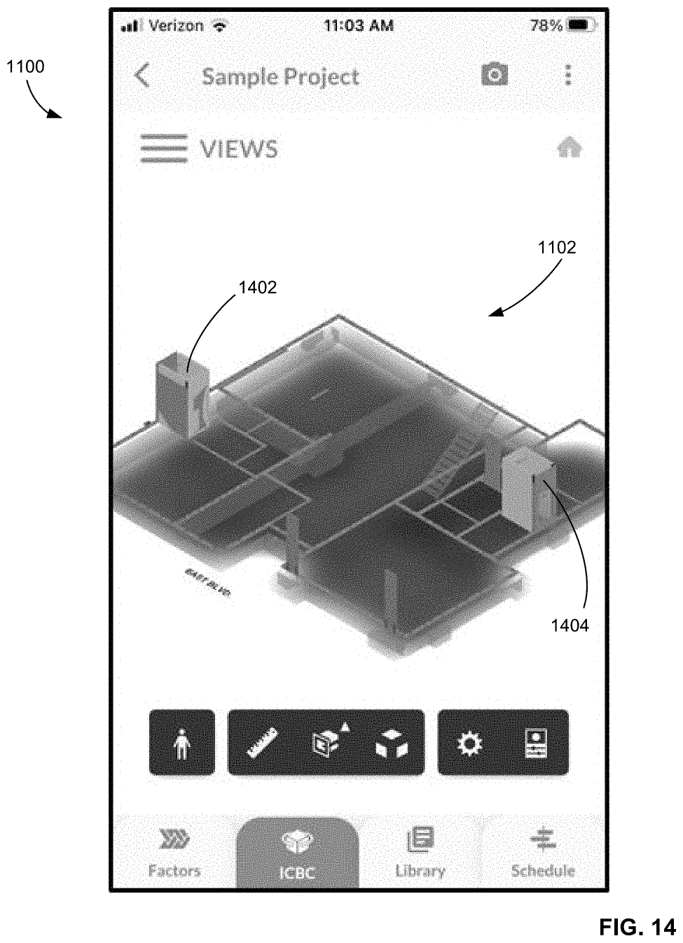

As shown in FIG. 13, the construction model interface 1100 can include a layer interface 1302. When selected, the layer interface 1302 can display various layers 1304a, 1304b, 1304c, for example. The layers 1304 correspond to various aspects of the construction model 1102. When a layer 1304 is selected in the layer interface 1302 only those components and/or materials that are part of that aspect of the construction model 1102 are displayed. For example, when layer 1304a Trenching Layout is selected, only those components in the trenching factor are displayed. Similarly, when Level 1 Core, layer 1304d, is selected only the cores that are positioned in the first floor of the construction model 1102 are displayed. FIG. 14 shows such a view of the construction model 1102. The construction model interface 1102 shown in FIG. 4 displays a first core 1402 and a second core 1404 in their respective locations in the construction model 1102.

In other examples, the construction model interface 1110 can include other tools to allow a user to interact and obtain information regarding one or more of the components, assembly or aspects of the construction model.

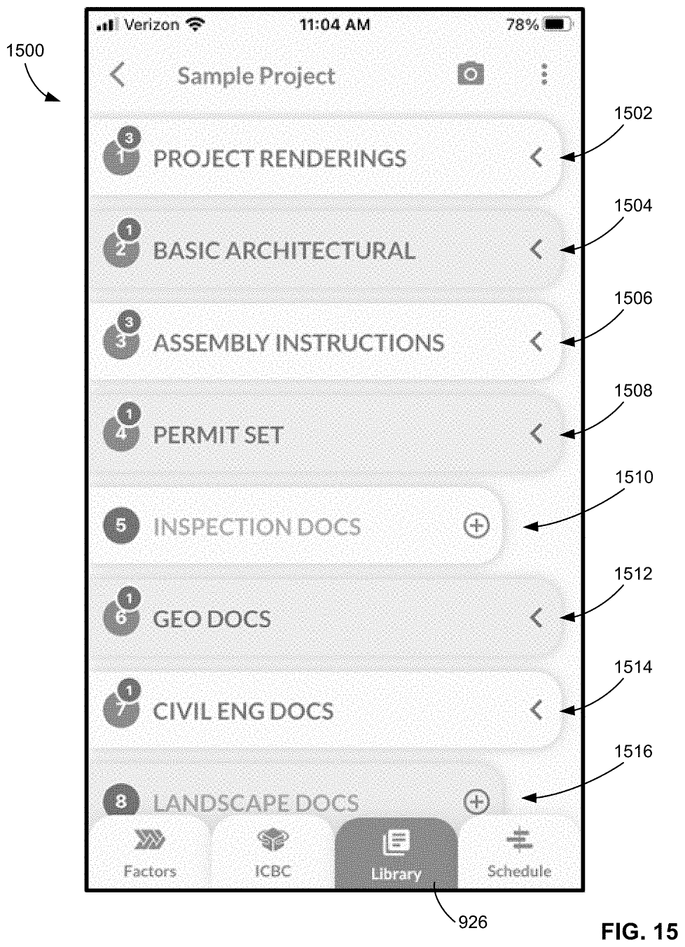

Referring now to FIG. 15, an example library interface 1500 of the construction application is shown. The library interface 1500 can be displayed, for example, when the library tab 926 is selected by a user. The library interface 1500 can include various tools to allow the user access and view data, information and other aspects of the construction project. In the example shown, the library interface 1500 can include project renderings interface 1502, architectural interface 1504, assembly instructions interface 1506, permit interface 1508, inspection interface 1510, geo interface 1512, civil engineering interface 1514 and landscape interface 1516. Still other interfaces can also be included in the library interface 1500 but are not shown in FIG. 15.

The project renderings interface 1502 can allow a user to access and/or view renderings or other images that show an appearance of the construction project when the construction project is completed. Architectural interface 1504 can allow a user to access and/or view architectural drawings for various aspects of the construction project. The assembly instructions interface 1506 can allow a user to access and/or view instructions for the assembly of components for the construction project. The assembly instructions interface 1506 can, for example, provide the assembly data 326 described above. The permit interface 1508 can allow a user to access and/or view permits that have been acquired or applied for relative to the construction project. The inspection interface 1510 can allow the user to access and/or view inspections that have been conducted, planned or are anticipated in connection with the construction project. The geo interface 1512 can allow the user to access and/or view geological survey or other geological information (e.g., soil reports) that are associated with the construction project. The civil engineering interface 1514 can allow a user to access and/or view engineering reports, schematics or other information about the construction project. The landscape interface 1516 can allow a user to access and/or view information, drawings, instructions or other information regarding landscaping that may be associated with the building project. The library interface 1500 is significant for maintenance and future modification that an owner or builder may want to undertake. In addition, it can provide information for future buyers that may be interested in purchasing a home built using the construction systems of the present disclosure.

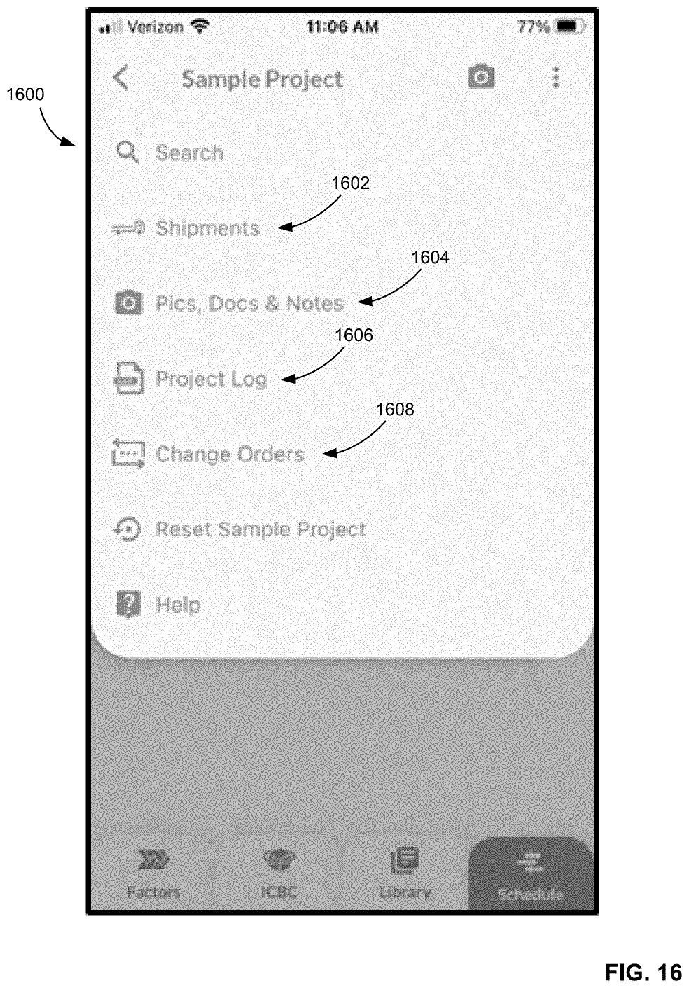

Referring now to FIG. 16, a scheduling interface 1600 is shown. The scheduling interface 1600 can be displayed, for example, when a user selects the schedule tab 928. The scheduling interface 1600 can display a schedule related to the construction plan. The schedule can includes dates and targets for completion of the various factors and for the completion and delivery of components and materials. The scheduling interface 1600 can display the schedule in any suitable format such as on a calendar or via Gantt chart or the like. The scheduling interface 1600 can include other tools to provide further information to the user. For example and as shown, the scheduling interface 1600 can include a shipment selector 1602, a pics, docs and notes selector 1604, a project log selector 1606, and a change order selector 1608.

Each of these selectors can allow a user to access and/or to display information regarding each of the selectors. The project log selector 1606 can cause a project log interface (not shown) to be launched that can allow the user to view past entries and information as well as to input additional information regarding the construction process and/or the construction project. The change order selector 1608 can cause a change order input interface to be launched that can allow a user to enter information about a modification or other change that is desired to the construction project. Such a change request, when accepted, can automatically cause the construction model and the resulting construction plan to change as well.

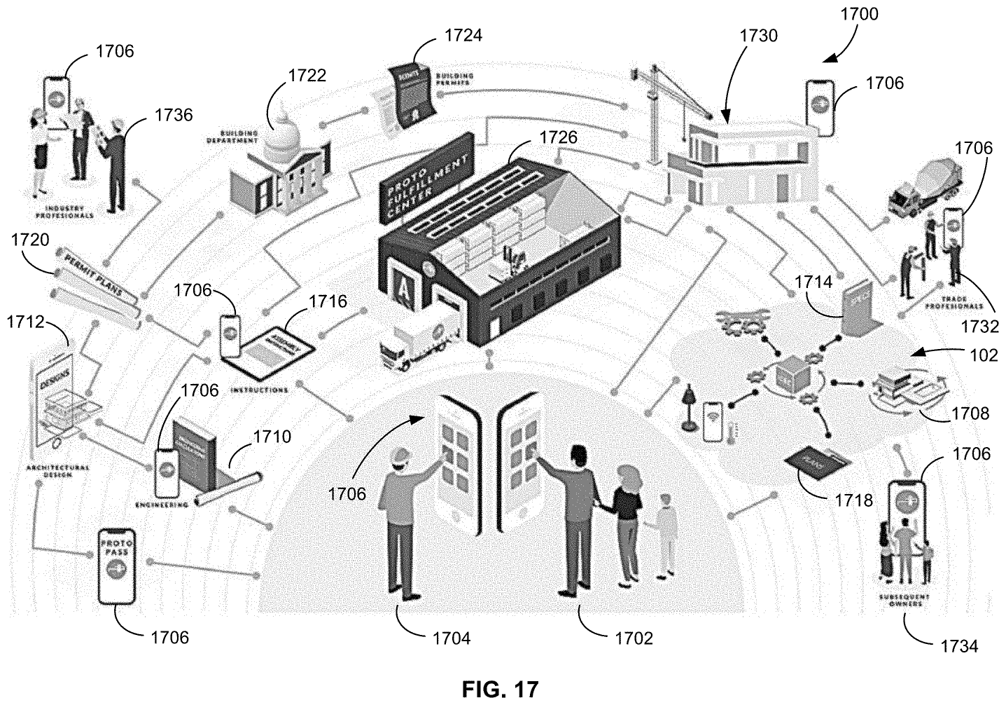

The construction systems of the present disclosure can operate in various environments such as in the context of the residential building industry. FIG. 17 illustrates and example environment 1700 in which the construction systems of the present disclosure may operate in. As shown, a user 1702 or builder/contactor 1704 can interact with the coordination platform 102 using the construction application 1706. As indicated by the mobile phone icon, the various stakeholders in the environment 1700 can also interact with the coordination platform 102 either directly or indirectly via a communication network, not shown.

After a user (e.g., a contractor/builder or customer) engages with the construction system, the entire construction process can be managed and synchronized using the coordination platform 102. During the initial stages, the construction project can be designed and engineered by affiliate service providers 1712, 1710, respectively. The construction project design can be translated or embodied in a centralized 3D construction model 1708 that can be stored in the coordination platform 102. The centralized 3D model 1708 can be used to create all documentary information such as design specifications 1714, drawings, renderings, etc. This documentation can then be used to create permit plans 1720 and shared with other industry professionals 1736 and submitted to regulatory authority 1722 to obtain the permits 1724 required to begin and/or execute the construction project.

The coordination platform 102 can also coordinate and determine a construction plan 1718 that can include assembly instructions 1716 and can group and allocate the building components and materials into the factors for the construction of the construction project. As determined by the construction plan 1718 and the determined factors, fabrication data, assembly data and/or factor data can be shared with fulfillment center 1726 for the manufacturing, fabrication and delivery of the components and materials to the building site 1730. Various trade professionals can use the delivered components and materials to complete the factors as scheduled and coordinated by the coordination platform 102. While all these actions are occurring the fulfillment centers 1726 and the trade professionals can be interacting with the coordination platform 102 to provide updates on status and progress on completion of tasks. With this information, the coordination platform 102 can share and/or allow access to status information to users such as general contractors 1704 and/or customers 1702.

Once the construction project is complete, the coordination platform 102 can also serve as an information repository for construction, maintenance and repair information for the subsequent owners 1734 of the construction project 1730.

As can be seen, the construction systems of the present disclosure and aspects thereof, such as coordination platform 102 provide improvement in efficiency, information sharing, coordination of information and construction tasks over known systems and methods. Furthermore, the construction systems of the present disclosure can provide further added value by serving as information sources regarding the construction, maintenance and repair of construction projects that were built using the construction system(s).

The example methods and apparatuses described herein may be at least partially embodied in the form of computer-implemented processes and apparatus for practicing those processes and/or the described functionality. The disclosed methods may also be at least partially embodied in the form of tangible, non-transient machine readable storage media encoded with computer program code. The media may include, for example, RAMs, ROMs, CD-ROMs, DVD-ROMs, BD-ROMs, hard disk drives, flash memories, or any other non-transient machine-readable storage medium, or any combination of these mediums, wherein, when the computer program code is loaded into and executed by a computer, the computer becomes an apparatus for practicing the method. The methods may also be at least partially embodied in the form of a computer into which computer program code is loaded and/or executed, such that, the computer becomes an apparatus for practicing the methods. When implemented on a general-purpose processor, the computer program code segments configure the processor to create specific logic circuits. The methods may alternatively be at least partially embodied in a digital signal processor formed of application specific integrated circuits for performing the methods.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A method of integrated component-based construction comprising:
receiving construction project input data comprising characteristics of a construction project;
preparing a centralized construction model based on the construction project input data and on a component library, the component library comprising a plurality of construction components having a plurality of predetermined characteristics;
determining a construction plan based on the centralized construction model comprising a plurality of factors, each factor in the plurality of factors describing a phase of construction;
sending fabrication instruction data and factor data based on the centralized construction model, the fabrication instruction data comprising fabrication instructions for the construction components in the centralized construction model, and the factor data comprising grouping instructions for the grouping of the construction components into each factor of the plurality of factors; and
sending assembly data based on the centralized construction model comprising instructions for completing each factor in the plurality of factors.

2. The method of claim 1, wherein each factor in the plurality of factors describes a subsequent phase of the construction plan.

3. The method of claim 1, wherein the centralized construction model is a three-dimensional electronic parametric model.

4. The method of claim 1, wherein the construction project input data is received from an affiliate partner via an electronic user interface.

5. The method of claim 1, wherein the fabrication instruction data and the factor data is sent to a fulfillment center in a predetermined geographical location relative to a building site for the construction project.

6. The method of claim 1, wherein the factor data further comprises delivery instructions that indicate a plurality of delivery times when the construction components for each factor in the plurality of factors is to be delivered to a building site.

7. The method of claim 6, wherein the plurality of delivery times are different times.

8. The method of claim 1, further comprising re-sending fabrication instruction and factor data after information is received that a previously scheduled factor has been completed.

9. The method of claim 1, further comprising monitoring a status of completion of each factor in the construction plan.

10. A coordination platform for coordinating integrated component-based construction projects, the platform comprising a computing device configured to:
receive construction project input data comprising characteristics of a construction project;
prepare a centralized construction model based on the construction project input data and on a component library, the component library comprising a plurality of construction components having a plurality of predetermined characteristics;
determine a construction plan based on the centralized construction model comprising a plurality of factors, each factor in the plurality of factors describing a phase of construction;
send fabrication instruction data and factor data based on the centralized construction model, the fabrication instruction data comprising fabrication instructions for the construction components in the centralized construction model, and the factor data comprising grouping instructions for the grouping of the construction components into each factor of the plurality of factors; and
send assembly data based on the centralized construction model comprising instructions for completing each factor in the plurality of factors.

11. The platform of claim 10, wherein each factor in the plurality of factors describes a subsequent phase of the construction plan.

12. The platform of claim 10, wherein the centralized construction model is a three-dimensional electronic parametric model.

13. The platform of claim 10, wherein the construction project input data is received from an affiliate partner via an electronic user interface.

14. The platform of claim 10, wherein the fabrication instruction data and the factor data is sent to a fulfillment center in a predetermined geographical location relative to a building site for the construction project.

15. The platform of claim 10, wherein the factor data further comprises delivery instructions that indicate a plurality of delivery times when the construction components for each factor in the plurality of factors is to be delivered to a building site.

16. The platform of claim 10, wherein the plurality of delivery times are different times.

17. The platform of claim 10, further comprising re-sending fabrication instruction and factor data after information is received that a previously scheduled factor has been completed.

18. The platform of claim 10, further comprising monitoring a status of completion of each factor in the construction plan.

19. A user interface for use in coordinating an integrated component-based construction project, the user interface configured to permit interaction by a user with a coordination platform, the user interface comprising:
a construction plan interface comprising information for a plurality of factors, the factors comprising groups of components and assembly instructions for a stage of construction;
a construction model interface comprising one or more tools for interacting and viewing a three-dimensional construction model; and
a library interface comprising user-selectable interfaces for accessing one or more repositories of information about the construction project.

20. The user interface of claim 19, wherein the one or more repositories of information comprises a project renderings interface, a permit interface, a geo interface and a landscape interface.
